(19) United States
(12) Patent Application Publication
(10) Pub. No.: US 2026/0271719 A1
(43) Pub. Date: Sep. 10, 2026

(54) PELTIER ELEMENT AND SEMICONDUCTOR PACKAGE

(71) Applicant: SONY SEMICONDUCTOR SOLUTIONS CORPORATION, KANAGAWA (JP)

(72) Inventor: TASUKU OGAMI, KANAGAWA (JP)

(21) Appl. No.: 19/126,615

(22) PCT Filed: Sep. 19, 2023
(86) PCT No.: PCT/JP2023/033860

§ 371 Date: May 18, 2026

(30) Foreign Application Priority Data
Nov. 8, 2022 (JP) 2022-178535

(51) Int. Cl. H10W 40/28; H10W 70/63; H10W 76/153; H10W 90/00

(52) U.S. Cl. CPC H10W 40/28; H10W 70/635; H10W 76/153; H10W 90/401; H10W 90/754; H10W 90/794

(57) ABSTRACT

To improve cooling performance of a semiconductor chip cooled by a Peltier element while enabling electrical connection with the outside. The Peltier element includes a thermoelectric element, a heat dissipation substrate that dissipates heat generated by the thermoelectric element, a cooling substrate that is cooled by the thermoelectric element, and an inter-substrate wiring that connects the heat dissipation substrate and the cooling substrate to each other. A spacer substrate provided between the heat dissipation substrate and the cooling substrate may be further included, and the inter-substrate wiring may connect the heat dissipation substrate and the cooling substrate to each other via the spacer substrate. A first through electrode that is connected to the inter-substrate wiring and penetrates the cooling substrate may be further included. A second through electrode that is connected to the inter-substrate wiring and penetrates the heat dissipation substrate may be further included.

### TECHNICAL FIELD

The present technology relates to a Peltier element and a semiconductor package. Specifically, the present technology relates to a Peltier element and a semiconductor package in which a heat dissipation substrate and a cooling substrate which are electrically connected to each other.

### BACKGROUND ART

In order to improve performance of a semiconductor device, a Peltier element that cools a semiconductor chip may be mounted on a semiconductor package. Here, in order to connect the semiconductor chip to the semiconductor package, wire bonding may be performed on the semiconductor chip. For example, there has been proposed an optical sensor device in which a pad portion of a sensor chip and a connection pin provided to a semiconductor package container are connected to each other via wire bonding (Refer to, for example, Patent Document 1).

### CITATION LIST

### Patent Document

Patent Document 1: Japanese Patent Application Laid-Open No. 2015-32707

### SUMMARY OF THE INVENTION

### Problems to be Solved by the Invention

However, in the above-described prior art, a bonding wire is connected to a relay substrate on which the sensor chip is mounted. Therefore, heat easily flows from the semiconductor package container to the sensor chip via the bonding wire, and there has been a possibility that cooling performance of the sensor chip is deteriorated.

The present technology has been made in view of such a situation, and an object thereof is to improve cooling performance of a semiconductor chip cooled by a Peltier element while enabling electrical connection with the outside.

### SOLUTIONS TO PROBLEMS

The present technology has been made to solve the above-described problems, and a first aspect of the present technology is a Peltier element including: a thermoelectric element; a heat dissipation substrate that dissipates heat generated by the thermoelectric element; a cooling substrate that is cooled by the thermoelectric element; and an inter-substrate wiring that connects the heat dissipation substrate and the cooling substrate to each other. This brings about an effect that the cooling substrate is connected to the outside via the inter-substrate wiring.

In addition, in the first aspect, a spacer substrate provided between the heat dissipation substrate and the cooling substrate may be further included, and the inter-substrate wiring may connect the heat dissipation substrate and the cooling substrate to each other via the spacer substrate. This brings about an effect that the cooling substrate and the heat dissipation substrate which are separated from each other by the thermoelectric element are connected to each other via the inter-substrate wiring.

In addition, in the first aspect, the inter-substrate wiring may penetrate the spacer substrate. This brings about an effect that the cooling substrate and the heat dissipation substrate are connected to each other while the cooling substrate and the heat dissipation substrate are separated from each other by the thermoelectric element.

In addition, in the first aspect, the inter-substrate wiring may be formed on a side surface of the spacer substrate. This brings about an effect that the cooling substrate and the heat dissipation substrate are connected to each other while the cooling substrate and the heat dissipation substrate are Separated from each other by the thermoelectric element.

In addition, in the first aspect, a wiring formed on the cooling substrate and a through electrode that is connected to the wiring and the inter-substrate wiring and penetrates the cooling substrate may be further included. This brings about an effect that the wiring formed on the cooling substrate is connected to the inter-substrate wiring while the inter-substrate wiring is disposed on the back surface side of the cooling substrate.

In addition, in the first aspect, a through electrode that is connected to the inter-substrate wiring and penetrates the heat dissipation substrate may be further included. This brings about an effect that the inter-substrate wiring is connected to the back surface side of the heat dissipation substrate while the inter-substrate wiring is disposed on the heat dissipation substrate.

In addition, in the first aspect, a drive electrode that is formed on the back surface side of the heat dissipation substrate and drives the thermoelectric element may be further included. This brings about an effect that the cooling substrate can be cooled via the thermoelectric element.

Furthermore, the second aspect is a semiconductor package including: a Peltier element in which a heat dissipation substrate that dissipates heat generated by a thermoelectric element and a cooling substrate that is cooled by the thermoelectric element are connected to each other via an inter-substrate wiring; and a semiconductor chip that is mounted on the cooling substrate and is electrically connected to the inter-substrate wiring. This brings about an effect that the semiconductor chip mounted on the cooling substrate is connected to the outside via the inter-substrate wiring.

In addition, in the second aspect, a wiring formed on the cooling substrate and connected to the inter-substrate wiring may be further included. This brings about an effect that the semiconductor chip mounted on the cooling substrate is connected to the inter-substrate wiring.

In addition, in the second aspect, the semiconductor chip may be connected to the wiring on the basis of flip-chip mounting on the cooling substrate. This brings about an effect that the semiconductor chip is connected to the outside without causing the heat dissipated from the heat dissipation substrate to flow into the semiconductor chip.

In addition, in the second aspect, the semiconductor chip is connected to the wiring via a bonding wire. This brings about an effect that heat generated in the semiconductor chip is released to the cooling substrate via the bonding wire.

In addition, in the second aspect, the semiconductor chip may be connected to the wiring on the basis of direct bonding onto the cooling substrate. This brings about an effect that the semiconductor chip is connected to the outside without causing the heat dissipated from the heat dissipation substrate to flow into the semiconductor chip.

In addition, in the second aspect, a mounting substrate on which the Peltier element is mounted may be further included.

This brings about an effect that the semiconductor chip mounted on the Peltier element is connected to the outside.

In addition, in the second aspect, the mounting substrate may include a ceramic substrate provided with a cavity in which the Peltier element is housed. This brings about an effect that the semiconductor chip is mounted on the mounting substrate while preventing protrusion of the semiconductor chip.

In addition, in the second aspect, an underfill provided between the heat dissipation substrate and the mounting substrate may be further included. This brings about an effect that heat dissipation from the Peltier element to the mounting substrate is improved.

In addition, in the second aspect, a first through electrode that is connected to the inter-substrate wiring and penetrates the cooling substrate and a second through electrode that is connected to the inter-substrate wiring and penetrates the heat dissipation substrate may be further included. This brings about an effect that the semiconductor chip mounted on the cooling substrate is connected to the outside via the first through electrode, the inter-substrate wiring, and the second through electrode in this order.

In addition, in the second aspect, a through electrode that is connected to the inter-substrate wiring and penetrates the cooling substrate, a bonding pad that is connected to the inter-substrate wiring and is formed on the heat dissipation substrate, and a bonding wire that is connected to the bonding pad may be further included. This brings about an effect that the semiconductor chip mounted on the cooling substrate is connected to the outside via the through electrode, the inter-substrate wiring, and the bonding wire in this order.

In addition, in the second aspect, a through electrode that is connected to the inter-substrate wiring and penetrates the cooling substrate, a bonding pad that is connected to the through electrode and is formed on the cooling substrate, and a bonding wire that is connected between the bonding pad and the semiconductor chip may be further included. This brings about an effect that the semiconductor chip mounted on the cooling substrate is connected to the outside via the bonding wire, the through electrode, and the inter-substrate wiring in this order, and the heat generated in the semiconductor chip is released to the cooling substrate via the bonding wire.

In addition, in the second aspect, a frame member provided on the semiconductor chip and a transparent substrate provided on the frame member may be further included. This brings about an effect that the semiconductor chip is sealed on the basis of the transparent substrate having the same size as the semiconductor chip.

In addition, in the second aspect, a frame member provided on the cooling substrate so as to surround the semiconductor chip and a transparent substrate provided on the frame member may be further included. This brings about an effect that the semiconductor chip can be sealed on the basis of the transparent substrate smaller than the Peltier element without forming an installation region of the frame member in the semiconductor chip.

### BRIEF DESCRIPTION OF DRAWINGS

FIG. 1 is a cross-sectional view illustrating a configuration example of a semiconductor package according to a first embodiment.

FIG. 2 is a plan view illustrating the configuration example of the semiconductor package according to the first embodiment.

FIG. 3 is a diagram illustrating a relationship between a chip temperature of a semiconductor chip mounted on the semiconductor package and a current for driving a Peltier element according to the first embodiment.

FIG. 4 is a cross-sectional view illustrating an example of a method for manufacturing a semiconductor package according to the first embodiment.

FIG. 5 is a cross-sectional view illustrating the example of the method for manufacturing the semiconductor package according to the first embodiment.

FIG. 6 is a cross-sectional view illustrating the example of the method for manufacturing the semiconductor package according to the first embodiment.

FIG. 7 is a cross-sectional view illustrating a configuration example of a semiconductor package according to a second embodiment.

FIG. 8 is a plan view illustrating the configuration example of the semiconductor package according to the second embodiment.

FIG. 9 is a cross-sectional view illustrating a configuration example of a semiconductor package according to a third embodiment.

FIG. 10 is a cross-sectional view illustrating a configuration example of a semiconductor package according to a fourth embodiment.

FIG. 11 is a cross-sectional view illustrating a configuration example of a semiconductor package according to a fifth embodiment.

FIG. 12 is a cross-sectional view illustrating a configuration example of a semiconductor package according to a six embodiment.

FIG. 13 is a cross-sectional view illustrating a configuration example of a semiconductor package according to a seventh embodiment.

FIG. 14 is a cross-sectional view illustrating a configuration example of a semiconductor package according to an eighth embodiment.

FIG. 15 is a diagram illustrating a configuration example of a Peltier element according to a ninth embodiment.

FIG. 16 is a diagram illustrating a configuration example of a Peltier element according to a tenth embodiment.

FIG. 17 is a block diagram illustrating a schematic configuration example of a vehicle control system.

FIG. 18 is an explanatory diagram illustrating an example of an installation position of an imaging section.

### MODE FOR CARRYING OUT THE INVENTION

Hereinafter, modes for carrying out the present technology (hereinafter referred to as embodiments) will be described. The description will be given in the following order.
1. First embodiment (Example in which a heat dissipation substrate and a cooling substrate are connected to each other via an inter-substrate wiring, and a semiconductor chip flip-chip mounted on the cooling substrate is connected to a mounting substrate via through electrodes respectively provided in the cooling substrate and the heat dissipation substrate)
2. Second embodiment (Example in which a heat dissipation substrate and a cooling substrate are connected to each other via an inter-substrate wiring, a semiconductor chip mounted on the cooling substrate is connected to the cooling substrate by wire bonding, and the heat dissipation substrate is connected to a mounting substrate by wire bonding)
3. Third embodiment (Example in which a heat dissipation substrate and a cooling substrate are connected to each other via an inter-substrate wiring, and a semiconductor chip mounted on the cooling substrate is connected to a mounting substrate via through electrodes respectively provided in the cooling substrate and the heat dissipation substrate while the semiconductor chip is connected to the cooling substrate by wire bonding)
4. Fourth embodiment (Example in which a heat dissipation substrate and a cooling substrate are connected to each other via an inter-substrate wiring, a semiconductor chip flip-chip mounted on the cooling substrate is connected to the inter-substrate wiring via a through electrode provided in the cooling substrate, and the heat dissipation substrate is connected to a mounting substrate by wire bonding)
5. Fifth embodiment (Example in which a heat dissipation substrate and a cooling substrate are connected to each other via an inter-substrate wiring, an underfill is filled between a semiconductor chip and the cooling substrate, and an underfill is filled between the heat dissipation substrate and a mounting substrate)
6. Sixth embodiment (Example in which a heat dissipation substrate and a cooling substrate are connected to each other via an inter-substrate wiring, and a semiconductor chip directly bonded onto the cooling substrate is connected to a mounting substrate via through electrodes respectively provided in the cooling substrate and the heat dissipation substrate)
7. Seventh embodiment (Example in which a heat dissipation substrate and a cooling substrate are connected to each other via an inter-substrate wiring, and a transparent substrate is disposed on a semiconductor chip flip-chip mounted on the cooling substrate)
8. Eighth embodiment (Example in which a heat dissipation substrate and a cooling substrate are connected to each other via an inter-substrate wiring, and a transparent substrate is disposed on the cooling substrate so as to cover a semiconductor chip flip-chip mounted on the cooling substrate)
9. Ninth Embodiment (Example in which a heat dissipation substrate and a cooling substrate are connected to each other via an inter-substrate wiring, and the inter-substrate wiring is disposed on both sides of thermoelectric element)
10. Tenth embodiment (Example in which a heat dissipation substrate and a cooling substrate are connected to each other via an inter-substrate wiring, and the inter-substrate wiring is disposed on a side surface of a spacer substrate between the heat dissipation substrate and the cooling substrate)
11. Example of application to mobile object

### 1. First Embodiment

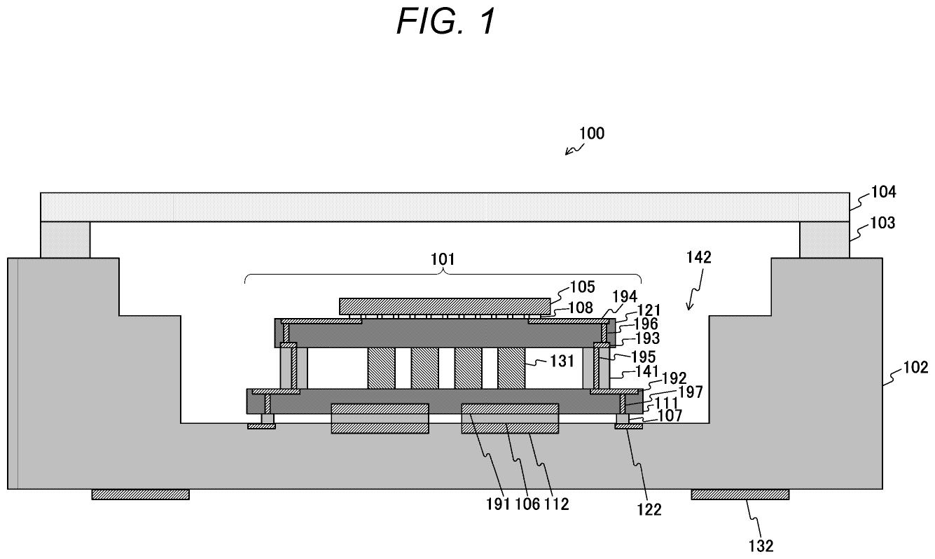

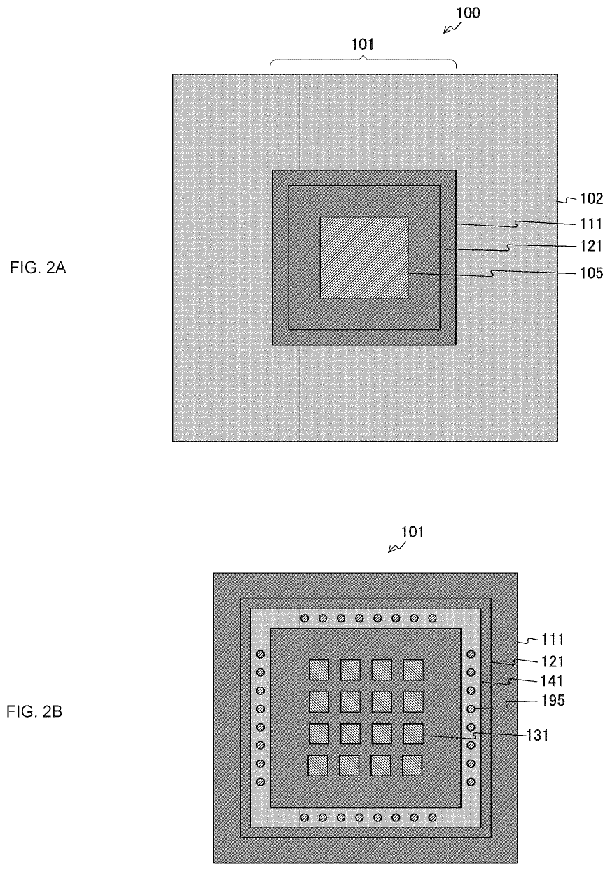

FIG. 1 is a cross-sectional view illustrating a configuration example of a semiconductor package according to a first embodiment, and FIG. 2 is a plan view illustrating the configuration example of the semiconductor package according to the first embodiment. Note that a of FIG. 2 is a plan view illustrating a schematic configuration example of a semiconductor package 100, and b of FIG. 2 is an enlarged plan view illustrating a schematic configuration example of a Peltier element 101.

In the drawing, the semiconductor package 100 includes the Peltier element 101, a ceramic substrate 102, and a semiconductor chip 105.

A cavity 142 capable of housing the Peltier element 101 is formed in the ceramic substrate 102. Furthermore, on a mounting surface of the ceramic substrate 102, a drive electrode 112 that drives the Peltier element 101 is formed, and a land electrode 122 electrically connected to the semiconductor chip 105 is formed. Furthermore, an external terminal 132 is formed on an outer surface of the ceramic substrate 102. The external terminal 132 may be a planar electrode, a bump electrode, or a lead electrode.

The Peltier element 101 cools the semiconductor chip 105 on the basis of the Peltier effect. The Peltier element 101 includes a heat dissipation substrate 111, a cooling substrate 121, and a thermoelectric element 131. The thermoelectric element 131 converts a potential difference into a temperature difference. The thermoelectric element 131 may be configured by combining a P-type semiconductor and an N-type semiconductor. At this time, the thermoelectric element 131 may have a pi-type structure including the P-type semiconductor and the N-type semiconductor connected in series.

The heat dissipation substrate 111 dissipates heat generated by the thermoelectric element 131. The cooling substrate 121 is cooled by the thermoelectric element 131. The heat dissipation substrate 111 and the cooling substrate 121 are disposed apart from each other with the thermoelectric element 131 interposed therebetween.

A wiring 192 is formed on the front surface side of the heat dissipation substrate 111. A drive electrode 191 is formed on the back surface side of the heat dissipation substrate 111. A through electrode 197 is formed in the heat dissipation substrate 111. The through electrode 197 is connected to the wiring 192.

A wiring 194 is formed on the front surface side of the cooling substrate 121. A back surface wiring 193 is formed on the back surface side of the cooling substrate 121. A through electrode 196 is formed in the cooling substrate 121. The through electrode 196 is connected to the wiring 194 and the back surface wiring 193.

A spacer substrate 141 is provided between the heat dissipation substrate 111 and the cooling substrate 121. The spacer substrate 141 may be disposed adjacent to the thermoelectric element 131. For example, the spacer substrate 141 may be disposed around an arrangement region of the thermoelectric element 131. In order to make it difficult for the heat dissipated from the heat dissipation substrate 111 to be transferred to the cooling substrate 121, the spacer substrate 141 may include a heat insulating material. The material of the spacer substrate 141 may be an insulator such as glass or resin, or a foamed material such as hard urethane foam.

An inter-substrate wiring 195 is formed in the spacer substrate 141. The inter-substrate wiring 195 electrically connects the heat dissipation substrate 111 and the cooling substrate 121 to each other. The inter-substrate wiring 195 may penetrate the spacer substrate 141 or may be formed along a side surface of the spacer substrate 141.

As the materials of the wirings 192 and 194, the back surface wiring 193, the through electrodes 196 and 197, and the inter-substrate wiring 195, for example, Cu, Al, TiN, TaN, WN, W, Ti, Ta, Ru, and Co can be used, and a laminated structure of a plurality of materials may be used.

The Peltier element 101 is mounted in the cavity 142. At this time, the drive electrode 191 is connected to the drive electrode 112 via a solder layer 106. The through electrode 197 is connected to the land electrode 122 via a solder layer 107.

The semiconductor chip 105 is flip-chip mounted on the cooling substrate 121. At this time, the semiconductor chip 105 can be connected to the wiring 194 via a bump electrode 108. The bump electrode 108 may be a solder ball or a pillar electrode. At this time, the semiconductor chip 105 is connected to the external terminal 132 via the bump electrode 108, the wiring 194, the through electrode 196, the back surface wiring 193, the inter-substrate wiring 195, the wiring 192, the through electrode 197, the solder layer 107, and the land electrode 122 in this order.

Semiconductor elements such as a transistor and a diode are formed in the semiconductor chip 105. The semiconductor elements may be integrated. In the semiconductor chip 105, a semiconductor memory such as a static random access memory (SRAM) or a dynamic random access memory (DRAM) may be formed.

Furthermore, in the semiconductor chip 105, a processor such as a central processing unit (CPU) or a graphics processing unit (GPU) may be formed. Furthermore, in the semiconductor chip 105, a hardware circuit such as a field-programmable gate array (FPGA) or an application specific integrated circuit (ASIC) may be formed. In the semiconductor chip 105, a signal processing circuit may be formed, a data processing circuit may be formed, an interface circuit may be formed, or an optical element may be formed. In the semiconductor chip 105, a solid-state imaging element may be formed. The solid-state imaging element may be a back-illuminated solid-state imaging element. The light received by the solid-state imaging element may be visible light, near infrared light (NIR), short wavelength infrared light (SWIR), ultraviolet light, X-ray, or the like. As the material of the semiconductor substrate used for the semiconductor chip 105, a semiconductor such as Si, SiC, GaN, GaAs, InP, InGaAs, or InGaAsP can be used.

A transparent substrate 104 is disposed on the ceramic substrate 102 so as to be positioned above the semiconductor chip 105. The transparent substrate 104 can be fixed to the ceramic substrate 102 via the adhesive layer 103. The material of the transparent substrate 104 may be glass, quartz, or a transparent resin such as polycarbonate or epoxy.

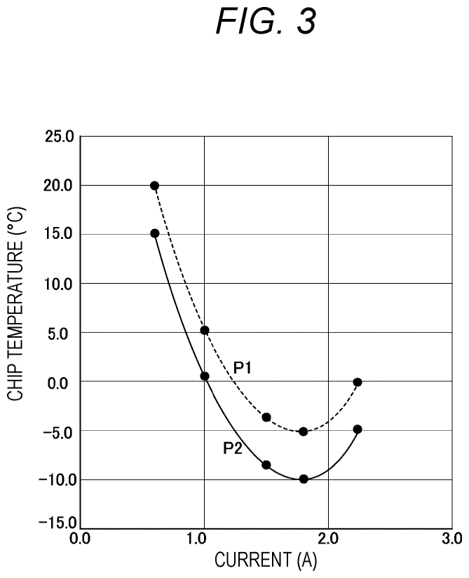

FIG. 3 is a diagram illustrating a relationship between a chip temperature of a semiconductor chip mounted on the semiconductor package and a current for driving a Peltier element according to the first embodiment. Note that P1 shows a chip temperature of the semiconductor chip 105 of the first embodiment described above. P2 shows a case where the semiconductor chip 105 of the first embodiment described above is directly connected to the ceramic substrate 102 by wire bonding.

In the drawing, as a current for driving the Peltier element 101 increases, a cooling capacity of the Peltier element 101 increases, and the chip temperature of the semiconductor chip 105 decreases. At this time, when the drive current for the Peltier element 101 is increased and the cooling capacity of the Peltier element 101 is increased, an amount of heat dissipation from the heat dissipation substrate 111 is also increased. Then, when heat flowing into the semiconductor chip 105 on the basis of the heat dissipation from the heat dissipation substrate 111 exceeds heat flowing out from the semiconductor chip 105 to the cooling substrate 121, the chip temperature of the semiconductor chip 105 changes from a decrease to an increase. Here, the heat dissipated from the heat dissipation substrate 111 is released to the outside mainly via the ceramic substrate 102. At this time, if the semiconductor chip 105 of the first embodiment described above is directly connected to the ceramic substrate 102 by wire bonding, the heat transferred from the heat dissipation substrate 111 to the ceramic substrate 102 flows into the Semiconductor chip 105 via the bonding wire, and cooling performance of the semiconductor chip 105 is deteriorated. On the other hand, the semiconductor chip 105 of the first embodiment described above is not directly connected to the ceramic substrate 102 by wire bonding. Therefore, the heat transferred from the heat dissipation substrate 111 to the ceramic substrate 102 can be prevented from flowing into the semiconductor chip 105 via the bonding wire, and the cooling performance of the semiconductor chip 105 can be improved.

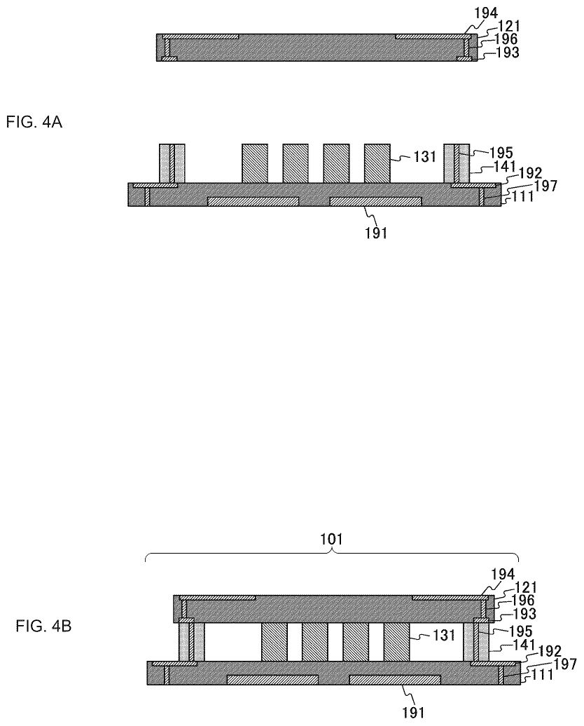

FIGS. 4 to 6 are diagrams illustrating an example of a method for manufacturing a semiconductor package according to the first embodiment.

In a of FIG. 4, the wiring 192 is formed on the front surface side of the heat dissipation substrate 111, the drive electrode 191 is formed on the back surface side of the heat dissipation substrate 111, and the through electrode 197 connected to the wiring 192 is formed in the heat dissipation substrate 111. Furthermore, the wiring 194 is formed on the front surface side of the cooling substrate 121, the back surface wiring 193 is formed on the back surface side of the cooling substrate 121, and the through electrode 196 connected to the wiring 194 and the back surface wiring 193 is formed in the cooling substrate 121. Moreover, the inter-substrate wiring 195 penetrating the spacer substrate 141 is formed. Then, the thermoelectric element 131 is disposed on the heat dissipation substrate 111, the spacer substrate 141 is disposed on the heat dissipation substrate 111 so as to be positioned around the arrangement region of thermoelectric element 131, and the inter-substrate wiring 195 is connected to the wiring 192.

Next, as illustrated in b of FIG. 4, the cooling substrate 121 is disposed on the thermoelectric element 131 and the spacer substrate 141, the inter-substrate wiring 195 is connected to the back surface wiring 193, and the Peltier element 101 is formed.

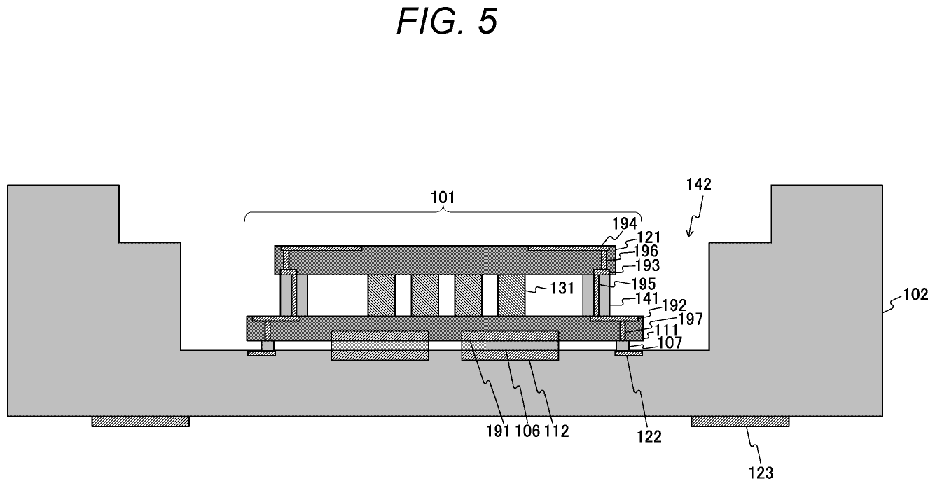

Next, as illustrated in FIG. 5, the Peltier element 101 is mounted in the cavity 142 of the ceramic substrate 102, the drive electrode 191 is connected to the drive electrode 112 via the solder layer 106, and the through electrode 197 is connected to the land electrode 122 via the solder layer 107.

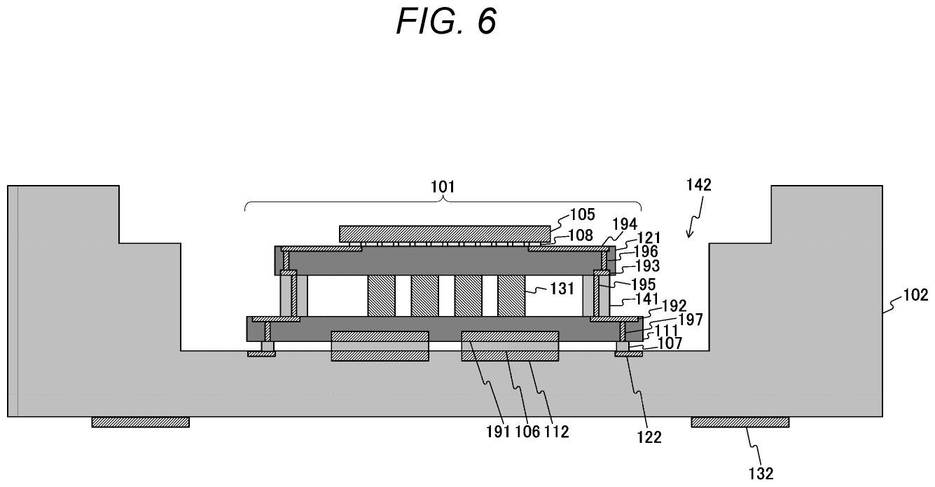

Next, as illustrated in FIG. 6, the semiconductor chip 105 is flip-chip mounted on the cooling substrate 121, and the semiconductor chip 105 is connected to the wiring 194 via the bump electrode 108.

Next, as illustrated in FIG. 1, the transparent substrate 104 is fixed on the ceramic substrate 102 via the adhesive layer 103.

As described above, in the first embodiment described above, the heat dissipation substrate 111 and the cooling substrate 121 are electrically connected to each other via the inter-substrate wiring 195, the through electrode 197 is provided in the heat dissipation substrate 111, and the through electrode 196 is provided in the cooling substrate 121. Then, the semiconductor chip 105 flip-chip mounted on the cooling substrate 121 is connected to the ceramic substrate 102 via the through electrode 196, the inter-substrate wiring 195, and the through electrode 197. With this arrangement, the semiconductor chip 105 on the cooling substrate 121 can be connected to the outside without directly connecting the semiconductor chip 105 to the ceramic substrate 102 via the bonding wire. Therefore, the heat released from the Peltier element 101 can be suppressed from flowing into the semiconductor chip 105, and the cooling performance of the semiconductor chip 105 can be improved.

### 2. Second Embodiment

In the first embodiment described above, the semiconductor chip 105 flip-chip mounted on the cooling substrate 121 has been connected to the ceramic substrate 102 via the through electrode 196, the inter-substrate wiring 195, and the through electrode 197. In the second embodiment, a semiconductor chip mounted on the cooling substrate 121 is connected to a ceramic substrate via a bonding wire connected to the cooling substrate 121, the inter-substrate wiring 195, and a bonding wire connected to the heat dissipation substrate 111.

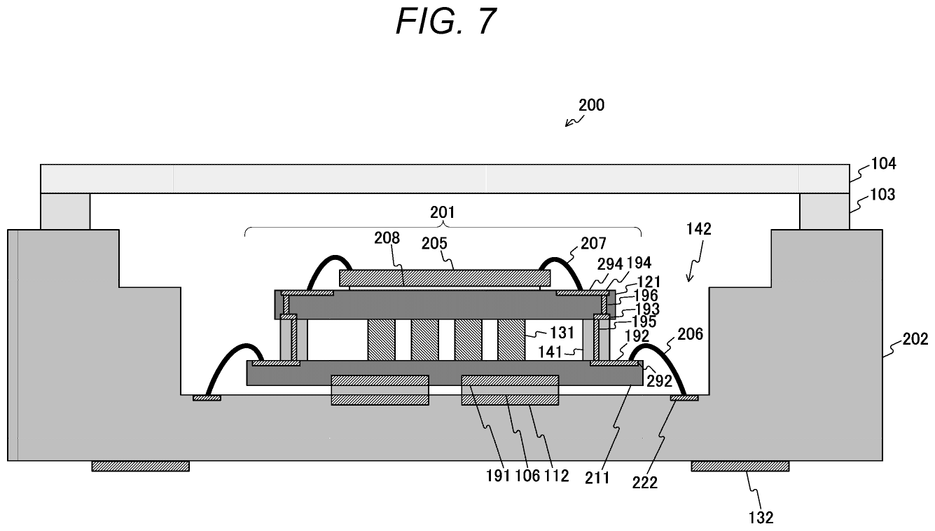

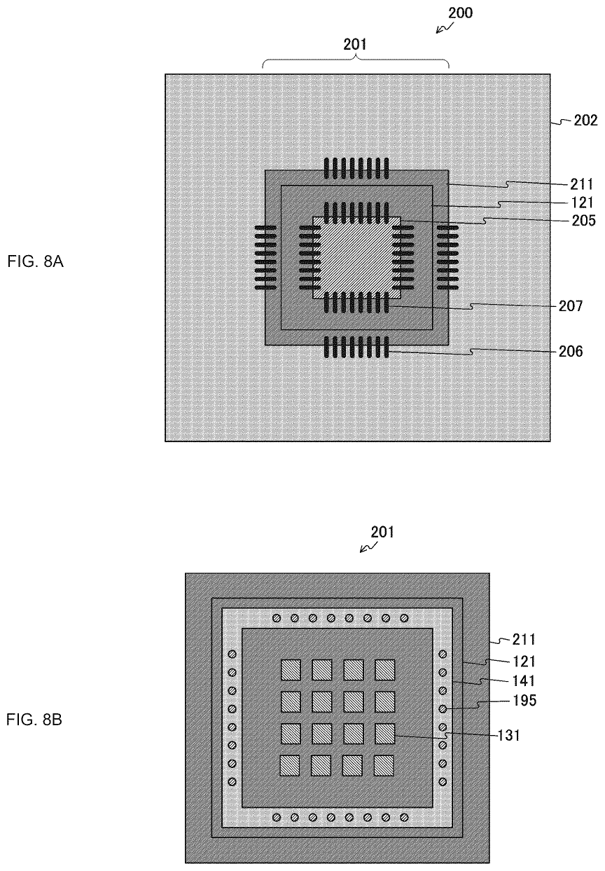

FIG. 7 is a cross-sectional view illustrating a configuration example of a semiconductor package according to the second embodiment, and FIG. 8 is a plan view illustrating the configuration example of the semiconductor package according to the second embodiment. Note that a of FIG. 8 is a plan view illustrating a schematic configuration example of a semiconductor package 200, and b of FIG. 8 is an enlarged plan view illustrating a schematic configuration example of a Peltier element 201.

In the drawing, the semiconductor package 200 includes the Peltier element 201, a ceramic substrate 202, and a semiconductor chip 205 instead of the Peltier element 101, the ceramic substrate 102, and the semiconductor chip 105 of the first embodiment described above. Other configurations of the semiconductor package 200 of the second embodiment are similar to the configuration of the semiconductor package 100 of the first embodiment described above.

The ceramic substrate 202 includes a bonding pad 222 instead of the land electrode 122 of the ceramic substrate 102 of the first embodiment described above. Other configurations of the ceramic substrate 202 of the second embodiment are similar to the configuration of the ceramic substrate 102 of the first embodiment described above. The bonding pad 222 is disposed outside a mounting surface of the Peltier element 201.

In the Peltier element 201, bonding pads 292 and 294 are added to the Peltier element 101 of the first embodiment described above. Other configurations of the Peltier element 201 of the second embodiment are similar to the configuration of the Peltier element 101 of the first embodiment described above. The bonding pad 294 is disposed on the front surface side of the cooling substrate 121 so as to be positioned outside the mounting surface of the semiconductor chip 105. The bonding pad 294 is connected to the wiring 194. The bonding pad 292 is disposed on the front surface side of the heat dissipation substrate 111 so as to be positioned outside the arrangement region of the cooling substrate 121. The bonding pad 292 is connected to the wiring 192. The bonding pad 292 is connected to the bonding pad 222 via a bonding wire 206.

The semiconductor chip 205 is mounted on the cooling substrate 121. Semiconductor elements such as a transistor and a diode are formed in the semiconductor chip 205. At this time, the semiconductor chip 205 may be face-up mounted. The semiconductor chip 205 is fixed on the cooling substrate 121 via a die bond material 208. The die bond material 208 may be an adhesive material, a paste material, or a solder material. The semiconductor chip 205 is connected to the bonding pad 294 via a bonding wire 207. As the material of the bonding wires 206 and 207, for example, Au or Al can be used.

At this time, the semiconductor chip 205 is connected to the external terminal 132 via the bonding wire 207, the bonding pad 294, the wiring 194, the through electrode 196, the back surface wiring 193, the inter-substrate wiring 195, the wiring 192, the bonding pad 292, the bonding wire 206, and the bonding pad 222 in this order.

As described above, in the above-mentioned second embodiment, the semiconductor chip mounted on the cooling substrate 121 is connected to the ceramic substrate 202 via the bonding wire 207, the inter-substrate wiring 195, and the bonding wire 206. With this arrangement, the heat generated in the semiconductor chip 205 can flow out to the cooling substrate 121 from the front surface side of the semiconductor chip 205 via the bonding wire 207 while flowing out to the cooling substrate 121 from the back surface side of the semiconductor chip 205, and heat released from the Peltier element 201 can be suppressed from flowing into the semiconductor chip 205.

Therefore, the cooling performance of the semiconductor chip 105 can be improved.

### 3. Third Embodiment

In the first embodiment described above, the semiconductor chip 105 flip-chip mounted on the cooling substrate 121 has been connected to the ceramic substrate 102 via the through electrode 196, the inter-substrate wiring 195, and the through electrode 197. In the third embodiment, the semiconductor chip 205 mounted on the cooling substrate 121 is connected to the ceramic substrate 102 via the bonding wire 207 connected to the cooling substrate 121, the inter-substrate wiring 195, and the through electrode 197 formed in the heat dissipation substrate 111.

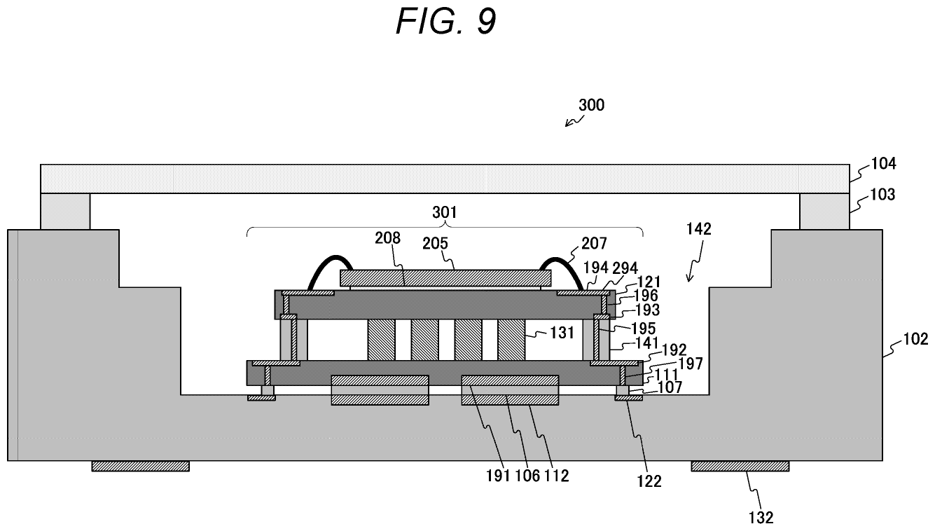

FIG. 9 is a cross-sectional view illustrating a configuration example of a semiconductor package according to the third embodiment.

In the drawing, a semiconductor package 300 includes a Peltier element 301, the ceramic substrate 102, and the semiconductor chip 205 instead of the Peltier element 101, the ceramic substrate 102, and the semiconductor chip 105 of the first embodiment described above. Other configurations of the semiconductor package 300 of the third embodiment are similar to the configuration of the semiconductor package 300 of the first embodiment described above.

In the Peltier element 301, the bonding pad 294 is added to the Peltier element 101 of the first embodiment described above. Other configurations of the Peltier element 301 of the third embodiment are similar to the configuration of the Peltier element 101 of the first embodiment described above.

The semiconductor chip 205 is connected to the bonding pad 294 via a bonding wire 207. At this time, the semiconductor chip 205 is connected to the external terminal 132 via the bonding wire 207, the bonding pad 294, the wiring 194, the through electrode 196, the back surface wiring 193, the inter-substrate wiring 195, the wiring 192, the through electrode 197, the solder layer 107, and the land electrode 122 in this order.

As described above, in the above-mentioned third embodiment, the semiconductor chip mounted on the cooling substrate 121 is connected to the ceramic substrate 102 via the bonding wire 207, the inter-substrate wiring 195, and the through electrode 197. With this arrangement, the heat generated in the semiconductor chip 205 can flow out to the cooling substrate 121 from the front surface side of the semiconductor chip 205 via the bonding wire 207 while flowing out to the cooling substrate 121 from the back surface side of the semiconductor chip 205, and heat released from the Peltier element 301 can be suppressed from flowing into the semiconductor chip 205. Therefore, the cooling performance of the semiconductor chip 105 can be improved without connecting the heat dissipation substrate 111 to the ceramic substrate 102 via the bonding wire 206.

### 4. Fourth Embodiment

In the first embodiment described above, the semiconductor chip 105 flip-chip mounted on the cooling substrate 121 has been connected to the ceramic substrate 102 via the through electrode 196, the inter-substrate wiring 195, and the through electrode 197. In the fourth embodiment, the semiconductor chip 105 flip-chip mounted on the cooling substrate 121 is connected to the ceramic substrate 202 via the through electrode 196 formed in the cooling substrate 121, the inter-substrate wiring 195, and the bonding wire 206 connected to the heat dissipation substrate 111.

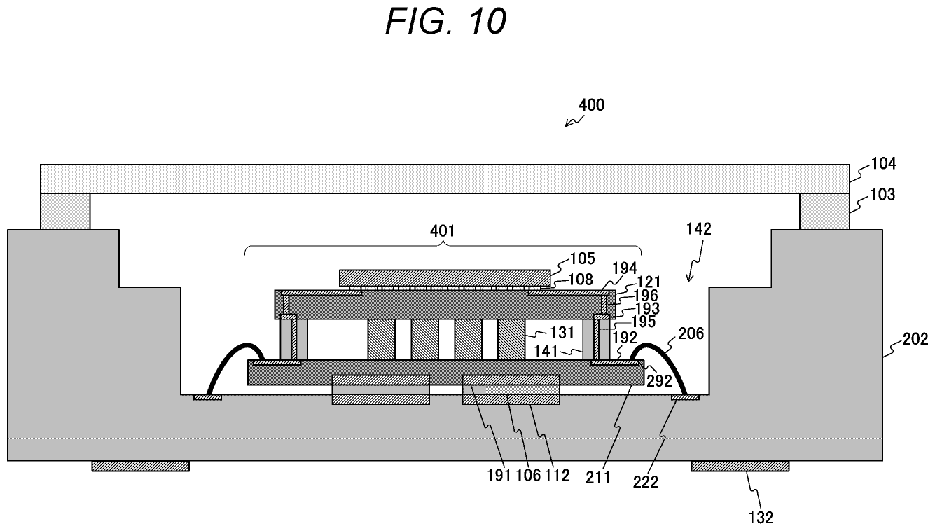

FIG. 10 is a cross-sectional view illustrating a configuration example of a semiconductor package according to the fourth embodiment.

In the drawing, a semiconductor package 400 includes a Peltier element 401 and the ceramic substrate 202 instead of the Peltier element 101 and the ceramic substrate 102 of the first embodiment described above. Other configurations of the semiconductor package 400 of the fourth embodiment are similar to the configuration of the semiconductor package 100 of the first embodiment described above.

In the Peltier element 401, the bonding pad 292 is added to the Peltier element 101 of the first embodiment described above. Other configurations of the Peltier element 401 of the fourth embodiment are similar to the configuration of the Peltier element 101 of the first embodiment described above. The bonding pad 292 is connected to the bonding pad 222 via a bonding wire 206.

At this time, the semiconductor chip 105 is connected to the external terminal 132 via the bump electrode 108, the wiring 194, the through electrode 196, the back surface wiring 193, the inter-substrate wiring 195, the wiring 192, the bonding pad 292, the bonding wire 206, and the bonding pad 222 in this order.

As described above, in the above-mentioned fourth embodiment, the semiconductor chip 105 flip-chip mounted on the cooling substrate 121 is connected to the ceramic substrate 202 via the through electrode 196, the inter-substrate wiring 195, and the bonding wire 206. With this arrangement, the heat released from the Peltier element 101 to the ceramic substrate 102 can be suppressed from flowing into the semiconductor chip 105, and the cooling performance of the semiconductor chip 105 can be improved.

### 5. Fifth Embodiment

In the first embodiment described above, the semiconductor chip 105 flip-chip mounted on the cooling substrate 121 has been connected to the ceramic substrate 102 via the through electrode 196, the inter-substrate wiring 195, and the through electrode 197. In the fifth embodiment, an underfill is filled between the semiconductor chip 105 flip-chip mounted on the cooling substrate 121 and the cooling substrate 121, and an underfill is filled between the heat dissipation substrate 111 and the ceramic substrate 102.

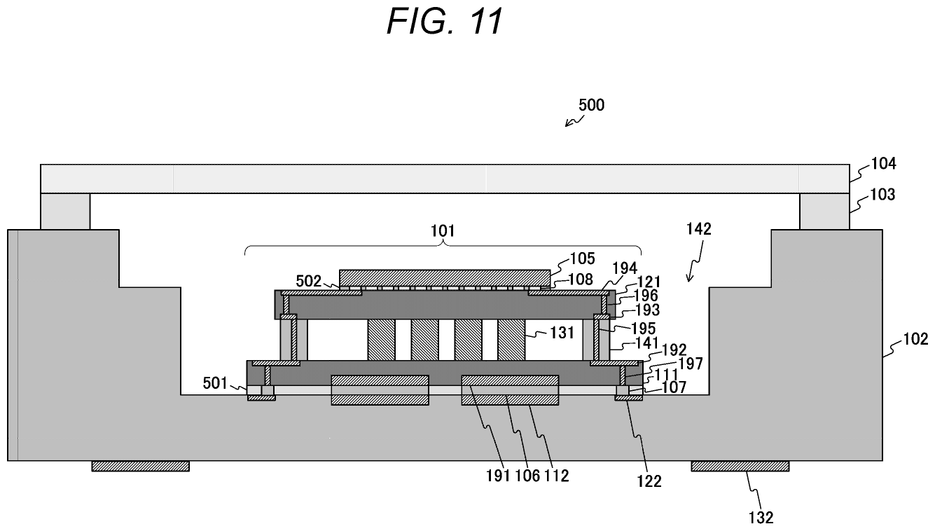

FIG. 11 is a cross-sectional view illustrating a configuration example of a semiconductor package according to the fifth embodiment.

In the drawing, in a semiconductor package 500, underfills 501 and 502 are added to the semiconductor package 100 of the first embodiment described above. Other configurations of the semiconductor package 500 of the fifth embodiment are similar to the configuration of the semiconductor package 100 of the first embodiment described above.

The underfill 501 is filled between the heat dissipation substrate 111 and the ceramic substrate 102. The underfill 502 is filled between the semiconductor chip 105 and the cooling substrate 121. As the material of the underfills 501 and 502, a thermosetting resin such as an epoxy resin can be used. In order to improve heat dissipation from the Peltier element 101 and the semiconductor chip 105, a material having high thermal conductivity may be used as the underfills 501 and 502. At this time, a filler such as Al₂O₃, AlN, BN, or BeO may be mixed into the underfills 501 and 502.

As described above, in the above-mentioned fifth embodiment, an underfill 502 is filled between the semiconductor chip 105 and the cooling substrate 121, and an underfill 501 is filled between the heat dissipation substrate 111 and the ceramic substrate 102. With this arrangement, heat dissipation from the Peltier element 101 and the semiconductor chip 105 can be improved, and mounting strength of the Peltier element 101 and the semiconductor chip 105 can be improved.

### 6. Sixth Embodiment

In the first embodiment described above, the semiconductor chip 105 flip-chip mounted on the cooling substrate 121 has been connected to the ceramic substrate 102 via the through electrode 196, the inter-substrate wiring 195, and the through electrode 197. In the sixth embodiment, the semiconductor chip 105 directly bonded onto the cooling substrate 121 is connected to the ceramic substrate 102 via the through electrode 196, the inter-substrate wiring 195, and the through electrode 197.

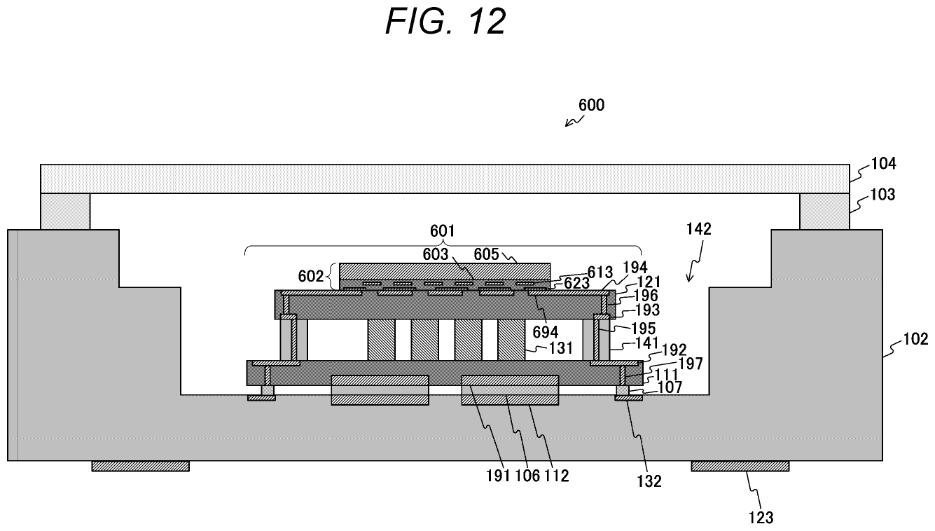

FIG. 12 is a cross-sectional view illustrating a configuration example of a semiconductor package according to the sixth embodiment.

In the drawing, a semiconductor package 600 includes a Peltier element 601 and a semiconductor chip 602 instead of the Peltier element 101 and the semiconductor chip 105 of the first embodiment described above. Other configurations of the semiconductor package 600 of the sixth embodiment are similar to the configuration of the semiconductor package 100 of the first embodiment described above.

In the Peltier element 601, a pad electrode 694 is added to the Peltier element 101 of the first embodiment described above. Other configurations of the Peltier element 601 of the sixth embodiment are similar to the configuration of the Peltier element 101 of the first embodiment described above.

The pad electrode 694 is formed in the cooling substrate 121 and is connected to the wiring 194. The pad electrode 694 can be used for direct bonding of the cooling substrate 121.

The semiconductor chip 602 is mounted on the cooling substrate 121. The semiconductor chip 602 includes a semiconductor layer 605 and a wiring layer 603. A semiconductor element can be formed on the semiconductor layer 605.

The wiring layer 603 is provided with a wire 613 and a pad electrode 623 embedded in an insulating layer. The pad electrode 623 can be used for direct bonding of the semiconductor chip 602. For example, hybrid bonding may be used to directly bond the semiconductor chip 602 to the cooling substrate 121.

In hybrid bonding, the pad electrode 623 is exposed on the surface of the wiring layer 603, the pad electrode 694 is exposed on the surface of the cooling substrate 121, and the pad electrodes 623 and 694 are formed at positions facing each other. At this time, Cu can be used as the material of each of the pad electrodes 623 and 694. As the material used for the insulating layer of the cooling substrate 121 and the wiring layer 603, for example, SiO₂, SiN, or SiCN can be used. In addition, each of the pad electrodes 623 and 694 is recessed by about several tens of nanometers from the surface of each of the wiring layer 603 and the cooling substrate 121. At this time, the plane size of each of the pad electrodes 623 and 694 can be set within a range of 0.1 μm to 10 μm. Then, after surface treatment of the insulating layers used for the cooling substrate 121 and the wiring layer 603 is performed, these insulating layers are brought into facing contact with each other, so that these insulating layers are connected to each other. At this time, a slight gap is formed between the pad electrodes 623 and 694. Then, the insulating layers used for the cooling substrate 121 and the wiring layer 603 are subjected to a heat treatment in a state of being pressure-bonded to each other, whereby the pad electrodes 623 and 694 expand, the pad electrodes 623 and 694 come into contact with each other, and interdiffusion of Cu causes a joint to be formed between the pad electrodes 623 and 694.

In this hybrid bonding, the plane size of each of the pad electrodes 623 and 694 can be set within a range of 0.1 μm to 10 μm. Therefore, as compared with the method of bonding the semiconductor chip 602 to the cooling substrate 121 via solder, the pitch of the bonding electrodes can be narrowed, and an increase in input and output to and from the semiconductor chip 602 can be accommodated.

As described above, in the above-mentioned sixth embodiment, the semiconductor chip 602 directly bonded onto the cooling substrate 121 is connected to the ceramic substrate 102 via the through electrode 196, the inter-substrate wiring 195, and the through electrode 197. With this arrangement, heat dissipation from the semiconductor chip 602 can be improved while suppressing the heat released from the Peltier element 601 to the ceramic substrate 102 from flowing into the semiconductor chip 602, and the cooling performance of the semiconductor chip 602 can be improved.

### 7. Seventh Embodiment

In the first embodiment described above, the Peltier element 101 has been mounted in the cavity 142 provided in the ceramic substrate 102, and the transparent substrate 104 has been disposed on the ceramic substrate 102. In the seventh embodiment, a transparent substrate is disposed on a semiconductor chip via a frame member provided on the semiconductor chip.

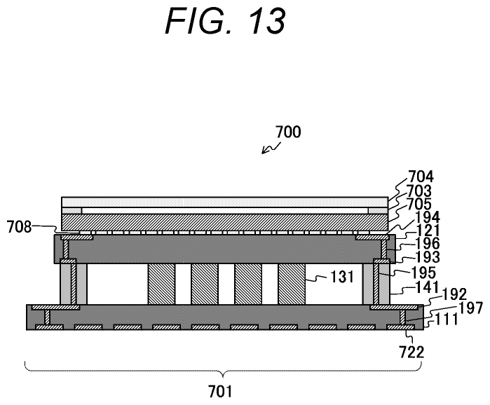

FIG. 13 is a cross-sectional view illustrating a configuration example of a semiconductor package according to the seventh embodiment.

In the drawing, a semiconductor package 700 includes the Peltier element 701 and a semiconductor chip 705.

In the Peltier element 701, a land electrode 722 is added to the Peltier element 101 of the first embodiment described above. Other configurations of the Peltier element 701 of the seventh embodiment are similar to the configuration of the Peltier element 101 of the first embodiment described above.

The land electrode 722 is formed on the back surface side of the heat dissipation substrate 111. The land electrode 722 is connected to the wiring 192 via the through electrode 197. The land electrode 722 can be used for mounting of the semiconductor package 700. A bump electrode such as a solder ball may be formed on the land electrode 722.

The semiconductor chip 705 is flip-chip mounted on the cooling substrate 121. A semiconductor element is formed on the semiconductor chip 705. The semiconductor chip 705 can be connected to the wiring 194 via a bump electrode 708. At this time, the semiconductor chip 705 is connected to the outside via the bump electrode 708, the wiring 194, the through electrode 196, the back surface wiring 193, the inter-substrate wiring 195, the wiring 192, the through electrode 197, and the land electrode 722 in this order.

A frame member 703 is disposed on the semiconductor chip 705. Here, in a case where a back-illuminated imaging element is formed on the semiconductor chip 705, the frame member 703 can be arranged around an imaging region where pixels are formed. The material of the frame member 703 may be resin or metal such as stainless steel. A transparent substrate 704 is disposed on the frame member 703 so as to be positioned above the semiconductor chip 705. An adhesive may be used to fix the frame member 703 to the semiconductor chip 705 and the transparent substrate 704. Here, the planar size of the transparent substrate 704 can be equal to the planar size of the semiconductor chip 705. At this time, on a semiconductor wafer in which the plurality of semiconductor chips 705 is integrated, a transparent wafer having the same plane size as the semiconductor wafer can be stacked via the frame member 703. Then, the laminated wafer may be divided into solid pieces by a method such as blade dicing to form the semiconductor package 700.

The semiconductor package 700 may be directly mounted on a circuit board or may be directly mounted on a mother board. In addition, a heat sink may be attached to the Peltier element 701.

As described above, in the above-mentioned seventh embodiment, the transparent substrate 704 is disposed on the semiconductor chip 705 via the frame member 703 provided on the semiconductor chip 705. With this arrangement, it is not necessary to use the ceramic substrate 102 provided with the cavity 142 in order to package the semiconductor chip 705, and the semiconductor package 700 can be downsized.

In addition, the semiconductor chip 705 can be packaged on the basis of the transparent substrate 704 having the same size as the semiconductor chip 705. Therefore, the transparent substrate 704 can be collectively arranged on the plurality of semiconductor chips 705 in a wafer state in which the plurality of semiconductor chips 705 is integrated, and the manufacturing efficiency of the semiconductor package 700 can be improved.

### 8. Eighth Embodiment

In the seventh embodiment described above, the transparent substrate 704 has been disposed on the semiconductor chip 705 via the frame member 703 provided on the semiconductor chip 705. In the eighth embodiment, a transparent substrate is disposed on a semiconductor chip via a frame member provided on the cooling substrate 121.

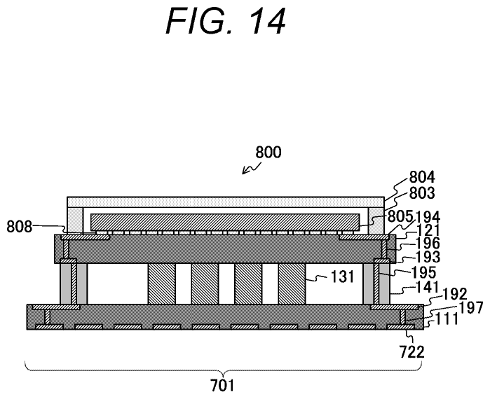

FIG. 14 is a cross-sectional view illustrating a configuration example of a semiconductor package according to the eighth embodiment.

In the drawing, a semiconductor package 800 includes a semiconductor chip 805, a frame member 803, and a transparent substrate 804 instead of the semiconductor chip 705, the frame member 703 and the transparent substrate 704 of the seventh embodiment described above. Other configurations of the semiconductor package 800 of the eighth embodiment are similar to the configuration of the semiconductor package 700 of the seventh embodiment described above.

The semiconductor chip 805 is flip-chip mounted on the cooling substrate 121. A semiconductor element is formed on the semiconductor chip 805. The semiconductor chip 805 can be connected to the wiring 194 via a bump electrode 808. At this time, the semiconductor chip 805 is connected to the outside via the bump electrode 808, the wiring 194, the through electrode 196, the back surface wiring 193, the inter-substrate wiring 195, the wiring 192, the through electrode 197, and the land electrode 722 in this order.

The frame member 803 is disposed on the cooling substrate 121 so as to surround the semiconductor chip 805. The transparent substrate 804 is disposed on the frame member 803 so as to be positioned above the semiconductor chip 805. An adhesive may be used to fix the frame member 803 to the cooling substrate 121 and the transparent substrate 804.

As described above, in the above-mentioned eighth embodiment, the transparent substrate 804 is disposed on the semiconductor chip 805 via the frame member 803 provided on the cooling substrate 121. With this arrangement, the semiconductor chip 805 can be packaged on the basis of the transparent substrate 804 smaller than the Peltier element 801 without forming an installation region of the frame member 803 in the semiconductor chip 805. Therefore, the semiconductor package 800 can be connected to the outside while reducing the size of the semiconductor package 800, and the circuit scale of the semiconductor chip 805 can be increased without increasing the planar size of the semiconductor chip 805.

### 9. Ninth Embodiment

In the first embodiment described above, the inter-substrate wiring 195 has been provided between the heat dissipation substrate 111 and the cooling substrate 121 so as to surround the thermoelectric element 131. In the ninth embodiment, the inter-substrate wiring is provided between the heat dissipation substrate and the cooling substrate so as to be located on both sides of the arrangement region of the thermoelectric element.

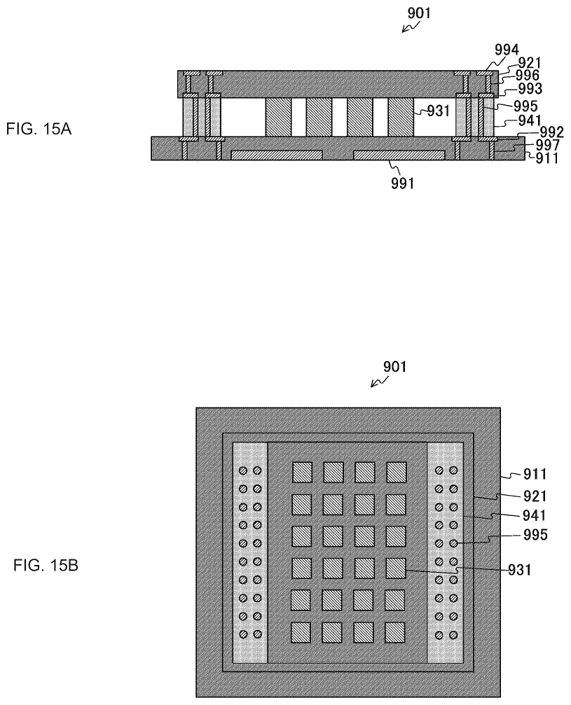

FIG. 15 is a diagram illustrating a configuration example of a Peltier element according to the ninth embodiment. Note that a of FIG. 15 is a cross-sectional view illustrating a configuration example of the Peltier element 101, and b of FIG. 15 is a plan view illustrating a schematic configuration example of the Peltier element 101.

In the drawing, the Peltier element 901 includes a heat dissipation substrate 911, a cooling substrate 921, and a thermoelectric element 931. The heat dissipation substrate 911 and the cooling substrate 921 are disposed apart from each other with the thermoelectric element 931 interposed therebetween.

A wiring 992 is formed on the front surface side of the heat dissipation substrate 911. A drive electrode 991 is formed on the back surface side of the heat dissipation substrate 911. A through electrode 997 is formed in the heat dissipation substrate 911. The through electrode 997 is connected to the wiring 992. The through electrode 997 can be formed on both sides of the arrangement region of thermoelectric element 931. The through electrodes 997 may be arranged in a plurality of rows on one side of the arrangement region of thermoelectric element 931.

A wiring 994 is formed on the front surface side of the cooling substrate 921. A back surface wiring 993 is formed on the back surface side of the cooling substrate 921. A through electrode 996 is formed in the cooling substrate 921. The through electrode 996 is connected to the wiring 994 and the back surface wiring 993. The through electrode 996 can be formed on both sides of the arrangement region of thermoelectric element 931. The through electrodes 996 may be arranged in a plurality of rows on one side of the arrangement region of thermoelectric element 931.

A spacer substrate 941 is provided between the heat dissipation substrate 911 and the cooling substrate 921. The spacer substrate 941 may be disposed adjacent to the arrangement region of the thermoelectric element 931. The spacer substrate 941 can be arranged on both sides of the arrangement region of thermoelectric element 931.

An inter-substrate wiring 995 is formed in the spacer substrate 941. The inter-substrate wiring 995 electrically connects the heat dissipation substrate 911 and the cooling substrate 921 to each other. The inter-substrate wiring 995 may penetrate the spacer substrate 941 or may be formed along a side surface of the spacer substrate 941. The inter-substrate wiring 995 may be arranged in a plurality of rows on one side of the arrangement region of thermoelectric element 931.

As described above, in the above-mentioned ninth embodiment, the inter-substrate wiring 995 is provided between the heat dissipation substrate 911 and the cooling substrate 921 so as to be located on both sides of the arrangement region of the thermoelectric element 931. With this arrangement, as compared with a case where the inter-substrate wiring 995 is provided around the arrangement region of the thermoelectric element 931, the arrangement region of the thermoelectric element 931 between the heat dissipation substrate 911 and the cooling substrate 921 can be increased, and the cooling capacity of the Peltier element 901 can be improved.

Note that the configuration in which the inter-substrate wiring 995 is provided between the heat dissipation substrate 111 and the cooling substrate 121 so as to be positioned on both sides of the thermoelectric element 931 may be applied to any of the semiconductor packages of the first to ninth embodiments described above.

### 10. Tenth Embodiment

In the first embodiment described above, the inter-substrate wiring 195 has been provided so as to penetrate the spacer substrate 141 between the heat dissipation substrate 111 and the cooling substrate 121. In the tenth embodiment, the inter-substrate wiring is disposed on the side surface of the spacer substrate between the heat dissipation substrate 111 and the cooling substrate 121.

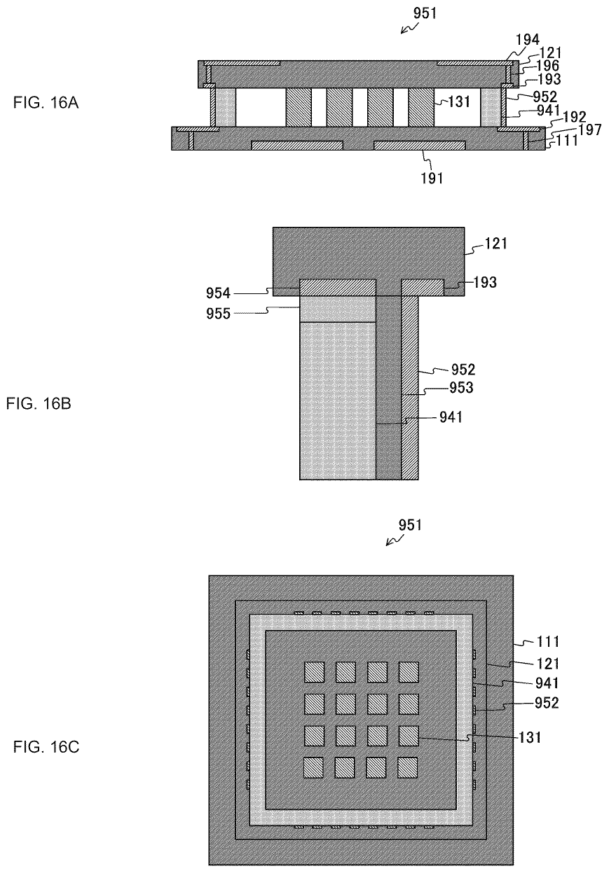

FIG. 16 is a diagram illustrating a configuration example of a Peltier element according to the tenth embodiment. Note that a of FIG. 16 is a cross-sectional view illustrating a configuration example of the Peltier element 951, and b of FIG. 16 is an enlarged cross-sectional view illustrating a part of the spacer substrate 141 where the inter-substrate wiring 195 is formed, and c of FIG. 16 is a plan view illustrating a schematic configuration example of the Peltier element 951.

In the drawing, the Peltier element 951 includes the spacer substrate 941 and the inter-substrate wiring 952 instead of the spacer substrate 141 and the inter-substrate wiring 195 of the first embodiment described above. Other configurations of the Peltier element 951 of the tenth embodiment are similar to the configuration of the Peltier element 101 of the first embodiment described above.

A spacer substrate 941 is provided between the heat dissipation substrate 111 and the cooling substrate 121. The spacer substrate 941 may be disposed adjacent to the arrangement region of the thermoelectric element 131. For example, spacer substrate 941 may be disposed around the arrangement region of thermoelectric element 131, or may be disposed on both sides of the arrangement region of thermoelectric element 131.

An inter-substrate wiring 952 is formed on the spacer substrate 941. The inter-substrate wiring 952 electrically connects the heat dissipation substrate 111 and the cooling substrate 121 to each other. An inter-substrate wiring 952 is formed on the side surface of the spacer substrate 941. Note that the inter-substrate wiring 952 may be formed on the both side surfaces of the spacer substrate 941. At this time, as illustrated in b of the drawing, the inter-substrate wiring 952 may be formed via the resist layer 953 formed on the side surface of the spacer substrate 941. In order to form the inter-substrate wiring 952 on the side surface of the spacer substrate 941, a molded interconnect device (MID) method may be used, or 3D printing may be used. At this time, the spacer substrate 941 may be connected to the cooling substrate 121 via a solder layer 955. A land electrode 954 to which the solder layer 955 is bonded may be formed on the back surface side of cooling substrate 121.

As described above, in the above-mentioned tenth embodiment, the inter-substrate wiring 952 is disposed on the side surface of the spacer substrate 941 between the heat dissipation substrate 111 and the cooling substrate 121. With this arrangement, it is not necessary to pass the inter-substrate wiring 952 through the spacer substrate 941, and the width of the spacer substrate 941 can be reduced. As a result, as compared with the configuration in which the inter-substrate wiring 195 is provided so as to penetrate through the spacer substrate 141, the arrangement region of the thermoelectric element 131 between the heat dissipation substrate 111 and the cooling substrate 121 can be increased, and the cooling capacity of the Peltier element 951 can be improved.

Note that the configuration in which the inter-substrate wiring 952 is provided on the side surface of the spacer substrate 941 between the heat dissipation substrate 111 and the cooling substrate 121 may be applied to any of the semiconductor packages of the first to ninth embodiments described above.

### 11. Example of Application to Mobile Object

The technology according to the present disclosure (the present technology) can be applied to various products. For example, the technology of the present disclosure may be achieved in the form of a device to be mounted on a mobile object of any kind, such as an automobile, an electric vehicle, a hybrid electric vehicle, a motorcycle, a bicycle, a personal mobility, an airplane, a drone, a vessel, or a robot.

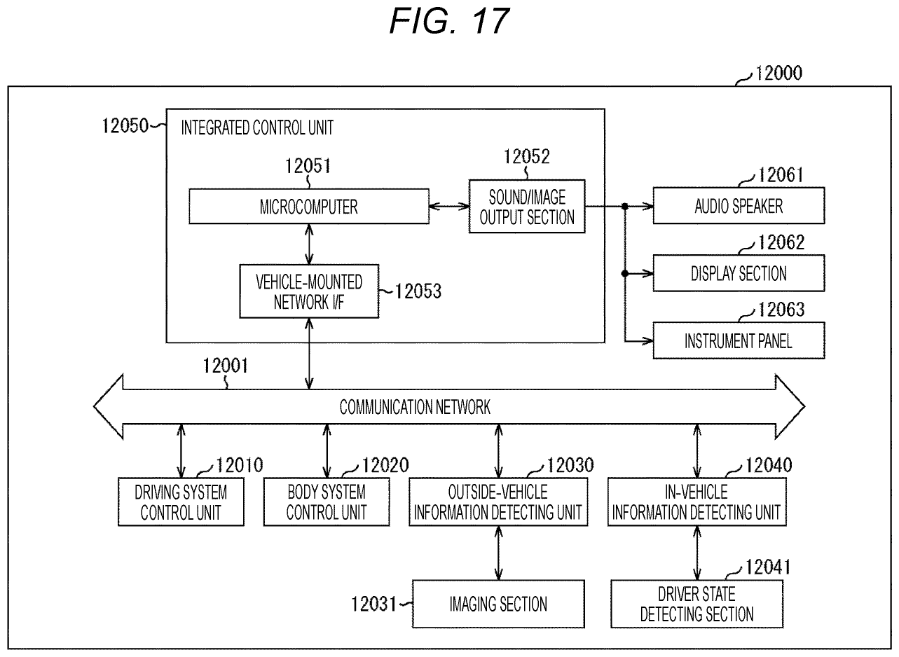

FIG. 17 is a block diagram illustrating a schematic configuration example of a vehicle control system as an example of a moving body control system to which the technology according to the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 17, as the output device, an audio speaker 12061, a display section 12062, and an instrument panel 12063 are illustrated. The display section 12062 may, for example, include at least one of an on-board display and a head-up display.

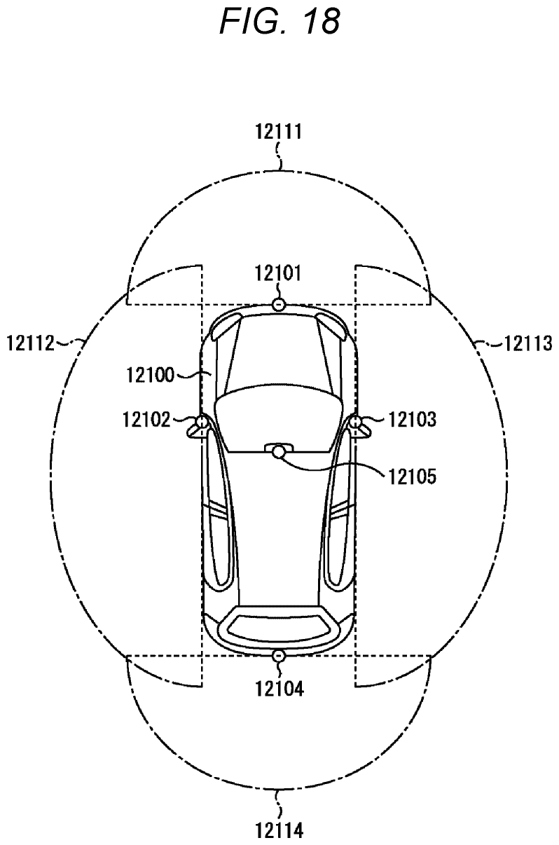

FIG. 18 is a diagram illustrating an example of the installation position of the imaging section 12031.

In FIG. 18, the imaging section 12031 includes imaging sections 12101, 12102, 12103, 12104, and 12105.

The imaging sections 12101, 12102, 12103, 12104, and 12105 are provided, for example, at positions such as a front nose, a sideview mirror, a rear bumper, a back door, and an upper portion of a windshield in the interior of a vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

It is to be noted that, FIG. 18 illustrates examples of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology of the present disclosure can be applied to the imaging section 12031 among the configurations described above. Specifically, for example, the above-described semiconductor packages 100 to 800 can be applied to the imaging section 12031 of the vehicle control system 12000. By applying the technology according to the present disclosure to the vehicle control system 12000, it is possible to obtain a captured image while suppressing the influence of noise.

Note that the embodiments described above show examples for embodying the present technology, and the matters in the embodiments and the matters specifying the invention in the claims have correspondence relationships. Similarly, the matters specifying the invention in the claims and matters with the same names in the embodiments of the present technology have correspondence relationships. However, the present technology is not limited to the embodiments, and can be embodied by applying various modifications to the embodiments without departing from the gist of the present technology. In addition, effects described in the present specification are merely examples and are not limited, and other effects may be provided.

Note that the present technology may also have the following configurations.
(1) A Peltier element including:
a thermoelectric element;
a heat dissipation substrate that dissipates heat generated by the thermoelectric element;
a cooling substrate that is cooled by the thermoelectric element; and
an inter-substrate wiring that connects the heat dissipation substrate and the cooling substrate to each other.
(2) The Peltier element according to (1), further including
a spacer substrate provided between the heat dissipation substrate and the cooling substrate, in which
the inter-substrate wiring connects the heat dissipation substrate and the cooling substrate to each other via the spacer substrate.
(3) The Peltier element according to (2), in which the inter-substrate wiring penetrates the spacer substrate.
(4) The Peltier element according to (2), in which
the inter-substrate wiring is formed on a side surface of the spacer substrate.
(5) The Peltier element according to any one of (1) to (4), further including:
a wiring formed on the cooling substrate; and
a through electrode that is connected to the wiring and the inter-substrate wiring and penetrates the cooling substrate.
(6) The Peltier element according to any one of (1) to (5), further including:
a through electrode that is connected to the inter-substrate wiring and penetrates the heat dissipation substrate.
(7) The Peltier element according to any one of (1) to (6), further including:
a drive electrode that is formed on a back surface side of the heat dissipation substrate and drives the thermoelectric element.
(8) A semiconductor package including:
a Peltier element in which a heat dissipation substrate that dissipates heat generated by a thermoelectric element and a cooling substrate that is cooled by the thermoelectric element are connected to each other via an inter-substrate wiring; and
a semiconductor chip that is mounted on the cooling substrate and is electrically connected to the inter-substrate wiring.
(9) The semiconductor package according to (8), further including
a wiring formed on the cooling substrate and connected to the inter-substrate wiring.
(10) The semiconductor package according to (9), in which
the semiconductor chip is connected to the wiring on a basis of flip-chip mounting on the cooling substrate.
(11) The semiconductor package according to (9), in which
the semiconductor chip is connected to the wiring via a bonding wire.
(12) The semiconductor package according to (9), in which
the semiconductor chip is connected to the wiring on a basis of direct bonding on the cooling substrate.
(13) The semiconductor package according to any one of (8) to (12), further including
a mounting substrate on which the Peltier element is mounted.
(14) The semiconductor package according to (13), in which
the mounting substrate includes a ceramic substrate provided with a cavity in which the Peltier element is housed.
(15) The semiconductor package according to (13) or (14), further including
an underfill provided between the heat dissipation substrate and the mounting substrate.
(16) The semiconductor package according to any one of (8) to (15), further including:
a first through electrode that is connected to the inter-substrate wiring and penetrates the cooling substrate; and
a second through electrode that is connected to the inter-substrate wiring and penetrates the heat dissipation substrate.
(17) The semiconductor package according to any one of (8) to (15), further including:
a through electrode that is connected to the inter-substrate wiring and penetrates the cooling substrate;
a bonding pad that is connected to the inter-substrate wiring and is formed on the heat dissipation substrate; and
a bonding wire that is connected to the bonding pad.
(18) The semiconductor package according to any one of (8) to (15), further including:
a through electrode that is connected to the inter-substrate wiring and penetrates the cooling substrate;
a bonding pad that is connected to the through electrode and is formed on the cooling substrate; and
a bonding wire that is connected between the bonding pad and the semiconductor chip.
(19) The semiconductor package according to any one of (8) to (18), further including:
a frame member provided on the semiconductor chip; and
a transparent substrate provided on the frame member.
(20) The semiconductor package according to any one of (8) to (18), further including:
a frame member provided on the cooling substrate so as to surround the semiconductor chip; and
a transparent substrate provided on the frame member.

### REFERENCE SIGNS LIST

100 Semiconductor package
101 Peltier element
111 Heat dissipation substrate
121 Cooling substrate
131 Thermoelectric element
141 Spacer substrate
192, 194 Wiring
112, 191 Drive electrode
193 Back surface wiring
195 Inter-substrate wiring
196, 197 Through electrode
102 Ceramic substrate
112 Drive electrode
122 Land electrode
132 External terminal
142 Cavity
103 Adhesive layer
104 Transparent substrate
105 Semiconductor chip
106, 107 Solder layer
108 Bump electrode

1. A Peltier element comprising:
a thermoelectric element;
a heat dissipation substrate that dissipates heat generated by the thermoelectric element;
a cooling substrate that is cooled by the thermoelectric element; and
an inter-substrate wiring that connects the heat dissipation substrate and the cooling substrate to each other.

2. The Peltier element according to claim 1 further comprising
a spacer substrate provided between the heat dissipation substrate and the cooling substrate, wherein
the inter-substrate wiring connects the heat dissipation substrate and the cooling substrate to each other via the spacer substrate.

3. The Peltier element according to claim 2, wherein
the inter-substrate wiring penetrates the spacer substrate.

4. The Peltier element according to claim 2, wherein t
he inter-substrate wiring is formed on a side surface of the spacer substrate.

5. The Peltier element according to claim 1, further comprising:
a wiring formed on the cooling substrate; and
a through electrode that is connected to the wiring and the inter-substrate wiring and penetrates the cooling substrate.

6. The Peltier element according to claim 1, further comprising:
a through electrode that is connected to the inter-substrate wiring and penetrates the heat dissipation substrate.

7. The Peltier element according to claim 1, further comprising:
a drive electrode that is formed on a back surface side of the heat dissipation substrate and drives the thermoelectric element.

8. A semiconductor package comprising:
a Peltier element in which a heat dissipation substrate that dissipates heat generated by a thermoelectric element and a cooling substrate that is cooled by the thermoelectric element are connected to each other via an inter-substrate wiring; and
a semiconductor chip that is mounted on the cooling substrate and is electrically connected to the inter-substrate wiring.

9. The semiconductor package according to claim 8, further comprising
a wiring formed on the cooling substrate and connected to the inter-substrate wiring.

10. The semiconductor package according to claim 9, wherein
the semiconductor chip is connected to the wiring on a basis of flip-chip mounting on the cooling substrate.

11. The semiconductor package according to claim 9, wherein
the semiconductor chip is connected to the wiring via a bonding wire.

12. The semiconductor package according to claim 9, wherein
the semiconductor chip is connected to the wiring on a basis of direct bonding on the cooling substrate.

13. The semiconductor package according to claim 8, further comprising
a mounting substrate on which the Peltier element is mounted.

14. The semiconductor package according to claim 13, wherein
the mounting substrate includes a ceramic substrate provided with a cavity in which the Peltier element is housed.

15. The semiconductor package according to claim 13, further comprising
an underfill provided between the heat dissipation substrate and the mounting substrate.

16. The semiconductor package according to claim 8, further comprising:
a first through electrode that is connected to the inter-substrate wiring and penetrates the cooling substrate; and
a second through electrode that is connected to the inter-substrate wiring and penetrates the heat dissipation substrate.

17. The semiconductor package according to claim 8, further comprising:
a through electrode that is connected to the inter-substrate wiring and penetrates the cooling substrate;
a bonding pad that is connected to the inter-substrate wiring and is formed on the heat dissipation substrate; and
a bonding wire that is connected to the bonding pad.

18. The semiconductor package according to claim 8, further comprising:
a through electrode that is connected to the inter-substrate wiring and penetrates the cooling substrate;
a bonding pad that is connected to the through electrode and is formed on the cooling substrate; and
a bonding wire that is connected between the bonding pad and the semiconductor chip.

19. The semiconductor package according to claim 8, further comprising:
a frame member provided on the semiconductor chip; and
a transparent substrate provided on the frame member.

20. The semiconductor package according to claim 8, further comprising:
a frame member provided on the cooling substrate so as to surround the semiconductor chip; and
a transparent substrate provided on the frame member.
